(19) United States
(12) Patent Application Publication
(10) Pub. No.: US 2026/0088264 A1
(43) Pub. Date: Mar. 26, 2026

(54) SUBSTRATE TREATING APPARATUS AND SEMICONDUCTOR MANUFACTURING EQUIPMENT INCLUDING THE SAME

(71) Applicant: Samsung Electronics Co., Ltd., Suwon-si (KR)

(72) Inventors: Sang Yoon LEE, Suwon-si (KR); Ji Mo LEE, Suwon-si (KR)

(21) Appl. No.: 19/239,074

(22) Filed: Jun. 16, 2025

(30) Foreign Application Priority Data
Sep. 23, 2024 (KR) 10-2024-0128300

(51) Int. Cl. H01J 37/32; H01L 21/677

(52) U.S. Cl. CPC H01J 37/32669; H01J 2237/3343; H10P 72/3218; H10P 72/3221

(57) ABSTRACT

A substrate treating apparatus includes a process chamber for treating a substrate, a magnetic field generator spaced apart from an outer surface of the process chamber and applying a first magnetic field to the process chamber, and a magnetic field mask disposed in a space between the process chamber and the magnetic field generator and applying a second magnetic field interfering with the first magnetic field. The magnetic field mask includes a ferromagnetic material.

### CROSS-REFERENCE TO RELATED APPLICATION

This application claims priority from Korean Patent Application No. 10-2024-0128300 filed on Sep. 23, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to a substrate treating apparatus seated in a semiconductor manufacturing plant and semiconductor manufacturing equipment including the same.

### Description of Related Art

In the case of substrate etching equipment, the ability to control variance of etched features is desirable to handle the increasing complexity of processes while ensuring yield. However, due to the limitation that it is difficult to make an electrostatic chuck (ESC) larger than the substrate, electrical discontinuity and thermal discontinuity inevitably occur near an edge of the substrate. These discontinuities lead to plasma non-uniformity, which naturally causes different process results between a center portion of the substrate and an edge portion of the substrate.

### SUMMARY

A technical purpose to be achieved in the present disclosure is to provide a substrate treating apparatus for securing plasma uniformity and semiconductor manufacturing equipment including the same.

The technical purposes of the present disclosure are not limited to the technical purposes as mentioned above, and other technical purposes as not mentioned may be clearly understood by those skilled in the art from descriptions as set forth below.

According to an aspect of the present disclosure, a substrate treating apparatus includes a process chamber for treating a substrate, a magnetic field generator spaced apart from an outer surface of the process chamber and configured to apply a first magnetic field to the process chamber, and a magnetic field mask disposed in a space between the process chamber and the magnetic field generator and configured to apply a second magnetic field interfering with the first magnetic field. The magnetic field mask includes a ferromagnetic material.

According to an aspect of the present disclosure, semiconductor manufacturing equipment includes a process processing module including a plurality of substrate treating apparatuses. One of the plurality of substrate treating apparatuses includes a process chamber for treating a substrate, a magnetic field generator spaced apart from an outer surface of the process chamber and configured to apply a first magnetic field to the process chamber, and a magnetic field mask disposed in a space between the process chamber and the magnetic field generator and configured to apply a second magnetic field interfering with the first magnetic field. The magnetic field mask includes a ferromagnetic material.

According to an aspect of the present disclosure, a substrate treating apparatus includes a process chamber for treating a substrate, a magnetic field generator spaced apart from an outer surface of the process chamber and configured to apply a first magnetic field to the process chamber, and a magnetic field mask disposed in a space between the process chamber and the magnetic field generator and configured to apply a second magnetic field interfering with the first magnetic field. The magnetic field mask includes a ferromagnetic material. The ferromagnetic material includes at least one of ferrite, permalloy, and silicon steel. The magnetic field mask has a main body and a pattern defined at a surface of the main body. The pattern includes at least one of a slit of a shape of a hole extending through the main body, a first groove defined at an upper surface of the main body, and a second groove defined at a lower surface of the main body. The pattern is defined in a portion of the surface of the main body. The outer surface of the process chamber includes at least one of an upper outer surface, a side outer surface, and a lower outer surface of the process chamber. The substrate treating apparatus is configured to perform one of an etching process, a cleaning process, and a deposition process.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 illustrates semiconductor manufacturing equipment including a substrate treating apparatus according to some embodiments of the present disclosure.

FIG. 2 illustrates semiconductor manufacturing equipment including a substrate treating apparatus according to some embodiments of the present disclosure.

FIG. 3 illustrates semiconductor manufacturing equipment including a substrate treating apparatus according to some embodiments of the present disclosure.

FIG. 4 illustrates an internal structure of a substrate treating apparatus according to some embodiments of the present disclosure.

FIG. 5 illustrates an internal structure of a process chamber constituting a substrate treating apparatus according to some embodiments of the present disclosure.

FIG. 6 illustrates an internal structure of a process chamber constituting a substrate treating apparatus according to some embodiments of the present disclosure.

FIG. 7 illustrates an internal structure of a process chamber constituting a substrate treating apparatus according to some embodiments of the present disclosure.

FIG. 8 illustrates an internal structure of a process chamber constituting a substrate treating apparatus according to some embodiments of the present disclosure.

FIG. 9 illustrates an internal structure of a substrate treating apparatus according to some embodiments of the present disclosure.

FIG. 10 illustrates an internal structure of a substrate treating apparatus according to some embodiments of the present disclosure.

FIG. 11 illustrates an internal structure of a substrate treating apparatus according to some embodiments of the present disclosure.

FIG. 12 illustrates an internal structure of a substrate treating apparatus according to some embodiments of the present disclosure.

FIG. 13 illustrates an internal structure of a substrate treating apparatus according to some embodiments of the present disclosure.

FIG. 14 illustrates an internal structure of a magnetic field generator constituting a substrate treating apparatus according to some embodiments of the present disclosure.

FIG. 15 illustrates a magnetic field mask constituting a substrate treating apparatus according to some embodiments of the present disclosure.

FIG. 16 illustrates a magnetic field mask constituting a substrate treating apparatus according to some embodiments of the present disclosure.

FIG. 17 illustrates a magnetic field mask constituting a substrate treating apparatus according to some embodiments of the present disclosure.

FIG. 18 illustrates a magnetic field mask constituting a substrate treating apparatus according to some embodiments of the present disclosure.

FIG. 19 illustrates a magnetic field mask constituting a substrate treating apparatus according to some embodiments of the present disclosure.

FIG. 20 illustrates a magnetic field mask constituting a substrate treating apparatus according to some embodiments of the present disclosure.

FIG. 21 illustrates a magnetic field mask constituting a substrate treating apparatus according to some embodiments of the present disclosure.

FIG. 22 illustrates a pattern in a magnetic field mask constituting a substrate treating apparatus according to some embodiments of the present disclosure.

FIG. 23 illustrates a pattern in a magnetic field mask constituting a substrate treating apparatus according to some embodiments of the present disclosure.

FIG. 24 illustrates a pattern in a magnetic field mask constituting a substrate treating apparatus according to some embodiments of the present disclosure.

FIG. 25 illustrates a pattern in a magnetic field mask constituting a substrate treating apparatus according to some embodiments of the present disclosure.

FIG. 26 illustrates a pattern within a magnetic field mask constituting a substrate treating apparatus according to some embodiments of the present disclosure.

FIG. 27 illustrates a pattern in a magnetic field mask constituting a substrate treating apparatus according to some embodiments of the present disclosure.

FIG. 28 illustrates a pattern within a magnetic field mask constituting a substrate treating apparatus according to some embodiments of the present disclosure.

FIG. 29 illustrates a pattern within a magnetic field mask constituting a substrate treating apparatus according to some embodiments of the present disclosure.

FIG. 30 illustrates a pattern in a magnetic field mask constituting a substrate treating apparatus according to some embodiments of the present disclosure.

FIG. 31 illustrates a pattern in a magnetic field mask constituting a substrate treating apparatus according to some embodiments of the present disclosure.

### DETAILED DESCRIPTIONS

Embodiments of the present disclosure will hereinafter be described with reference to the accompanying drawings. The same reference numerals are used for identical components in the drawings, and redundant explanations for these components are omitted.

The substrate treating apparatus may include a magnetic field mask to secure plasma uniformity. Hereinafter, semiconductor manufacturing equipment including a substrate treating apparatus will be described first, and subsequently the substrate treating apparatus will be described.

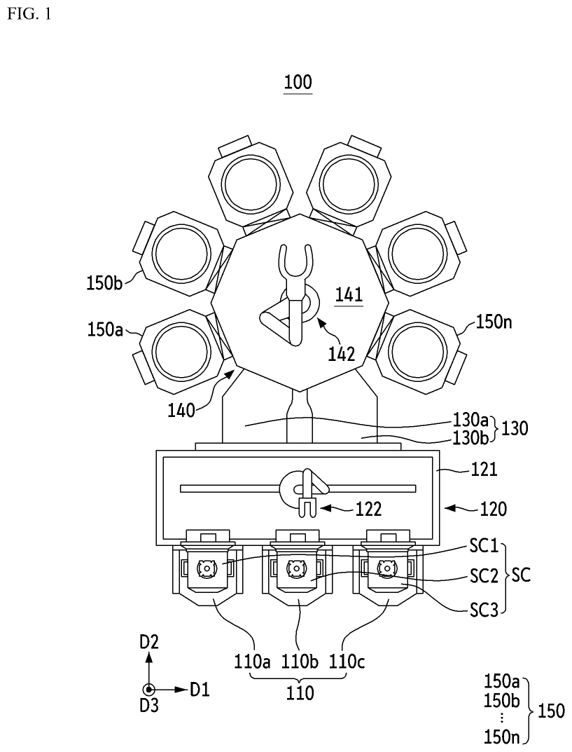

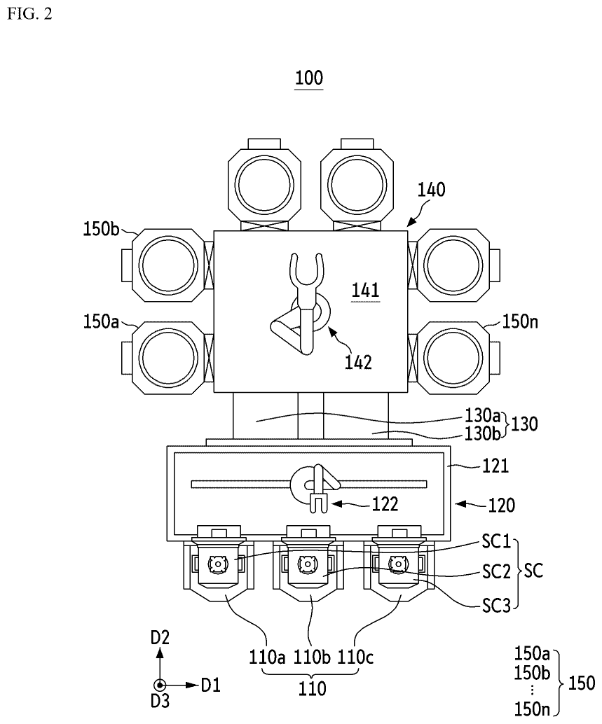

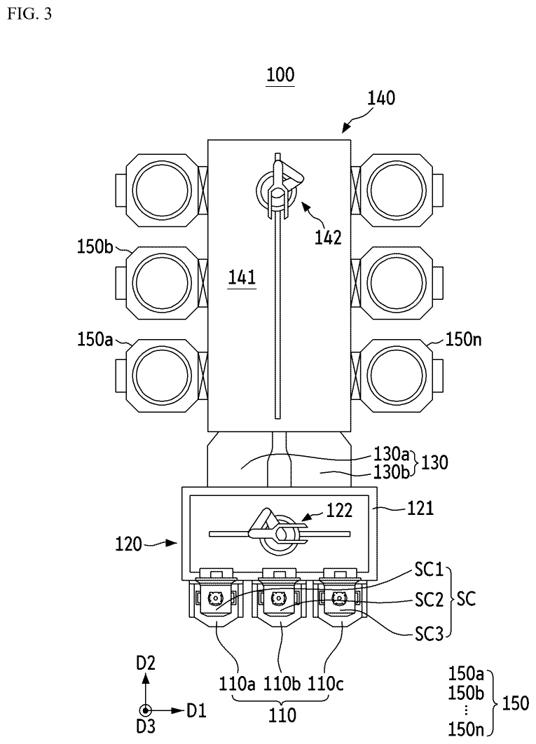

FIG. 1 illustrates semiconductor manufacturing equipment including a substrate treating apparatus of some embodiments of the present disclosure. FIG. 2 illustrates semiconductor manufacturing equipment including a substrate treating apparatus of some embodiments of the present disclosure. FIG. 3 illustrates semiconductor manufacturing equipment including a substrate treating apparatus of some embodiments of the present disclosure.

A first direction D1 and a second direction D2 may define a two-dimensional plane. The first direction D1 may be an X-axis direction, and the second direction D2 may be a Y-axis direction. When semiconductor manufacturing equipment is viewed at the front thereof, the first direction D1 may be a left-right direction, and the second direction D2 may be a front-back direction. Alternatively, the first direction D1 may be a forward-backward direction, and the second direction D2 may be a left-right direction. The first direction D1, the second direction D2 and a third direction D3 may define a three-dimensional space. The third direction D3 is a direction perpendicular to the plane defined by the first direction D1 and the second direction D2. The third direction D3 may be a Z-axis direction. The third direction D3 may be a vertical direction.

Referring to FIG. 1 to FIG. 3, semiconductor manufacturing equipment 100 may be configured to include a load port module 110, an index module 120, a buffer module 130, a transfer module 140, and a process processing module 150.

The semiconductor manufacturing equipment 100 may include the process processing module 150. The process processing module 150 may include a plurality of substrate treating apparatuses 150a, 150b, . . . , 150n. Each of the substrate treating apparatuses 150a, 150b, . . . , 150n may perform one process among an etching process, a cleaning process, a deposition process, and an ion implantation process. The plurality of substrate treating apparatuses 150a, 150b, . . . , 150n may be provided to be of the same type apparatus. However, embodiments of the present disclosure are not limited thereto and the plurality of substrate treating apparatuses 150a, 150b, . . . , 150n may be provided to be of different type apparatuses. The process processing module 150 may include a single substrate treating apparatus.

The load port module 110 may provide a seat surface on which a container SC is seated. The container SC may be transported to the load port module 110 by an overhead transport apparatus or a ground transport apparatus. The container SC may accommodate therein a plurality of substrates. For example, the container SC may be provided as a FOUP (Front Opening Unified Pod). The overhead transport apparatus may move along rails installed on a ceiling of the semiconductor manufacturing plant and transport the container SC. For example, the overhead transport apparatus may be provided as an OHT (Overhead Hoist Transport). The ground-based transport apparatus may move on a ground of the semiconductor manufacturing plant and transport the container SC. For example, the ground-based transport apparatus may be provided as an AMR (Autonomous Mobile Robot) or an AGV (Automatic Guided Vehicle).

The container SC may be loaded into or unloaded from the load port module 110. The substrates stored in the container SC may be loaded into or unloaded from the load port module 110.

In some embodiments, a container transport apparatus may load or unload the container SC into or from the load port module 110. For example, to load the container SC into the load port module 110, the container transport apparatus may grip the container SC and place the container SC onto the load port module 110. Furthermore, the container SC may be unloaded from the load port module 110 by the container transport apparatus gripping the container SC that has been seated onto the load port module 110. The container transport apparatus may be the overhead transport apparatus or the ground-based transport apparatus.

In some embodiments, a first transport robot 122 may load or unload a substrate into or from the container SC seated on the load port module 110. In unloading the substrate, when the container SC has been seated on the load port module 110, the first transport robot 122 approaches the load port module 110, and may then take out the substrate from an inside of the container SC. In loading the substrate, when the processing of the substrate has been completed within the process processing module 150, the first transport robot 122 takes out the substrate from an inside of the buffer module 130, and may then place the substrate into the container SC. As will be described later, the first transport robot 122 may be constructed in the index module 120.

A load port module 110 may be disposed in front of the index module 120. For example, the load port module 110 may include three load ports such as a first load port 110a, a second load port 110b, and a third load port 110c which may be disposed in front of the index module 120. The three load ports 110a, 110b, and 110c may be arranged in the horizontal direction D1. However, embodiments of the present disclosure are not limited thereto and the three load ports 110a, 110b, and 110c may be arranged in the vertical direction D3.

When the load port module 110 includes the three load ports 110a, 110b, and 110c, the containers SC respectively seated on the load ports 110a, 110b, and 110c may store therein different types of objects, respectively. For example, a first container SC1 seated on the first load port 110a may store therein a wafer-type sensor, a second container SC2 seated on the second load port 110b may store therein a substrate, and a third container SC3 seated on the third load port 110c may store therein a consumable part such as a focus ring and an edge ring. However, the present disclosure is not limited thereto, and the containers SC respectively seated on the load ports 110a, 110b, and 110c may store therein objects of the same type, respectively. Alternatively, the containers SC respectively seated on some load ports among a plurality of load ports may store therein objects of the same type, respectively.

The index module 120 may be disposed between the load port module 110 and a buffer module 130. The index module 120 may be provided as an interface for substrate transfer between the load port module 110 and the buffer module 130. The index module 120 may include a first module housing 121 and the first transport robot 122. The first module housing 121 may have an atmospheric pressure environment in an inside thereof. The first transport robot 122 may be disposed inside the first module housing 121 and may transport the substrate in the atmospheric pressure environment. The first transport robot 122 may include a single first transport robot or a plurality of first transport robots inside the first module housing 121.

Although not shown in FIG. 1 to FIG. 3, the index module 120 may include a buffer chamber. The buffer chamber may temporarily store therein a non-treated substrate before transporting the same to the buffer module 130. The buffer chamber may temporarily store therein a treated substrate before transporting the same to the container SC on the load port module 110. The buffer chamber may include a single buffer chamber or a plurality of buffer chambers defined in an inner wall of the first module housing 121.

The semiconductor manufacturing equipment 100 may include an equipment front end module (EFEM). The equipment front end module may include the load port module 110 and the index module 120.

The buffer module 130 may be disposed between the index module 120 and the transfer module 140. The buffer module 130 may accommodate a buffer stage therein. The buffer stage may temporarily store therein a non-treated substrate or a treated substrate. The buffer module 130 may include a plurality of load lock chambers. For example, the buffer module 130 may include a first load lock chamber 130a and a second load lock chamber 130b.

The two load lock chambers 130a and 130b may be arranged in the horizontal direction D1. However, embodiments of the present disclosure are not limited thereto, and the two load lock chambers 130a and 130b may be arranged in the vertical direction D3. The two load lock chambers 130a and 130b may be arranged in the same direction as the arrangement direction of the three load ports 110a, 110b, and 110c, or in a different direction from the arrangement direction of the three load ports 110a, 110b, and 110c.

The first load lock chamber 130a and the second load lock chamber 130b may provide different functions. For example, one of the first load lock chamber 130a and the second load lock chamber 130b may store therein the non-treated substrate, while the other thereof may store therein the treated substrate. However, the present disclosure is not limited thereto, and the first load lock chamber 130a and the second load lock chamber 130b may provide the same function. Each of the first load lock chamber 130a and the second load lock chamber 130b may store therein any substrate regardless of whether the substate has been treated.

The buffer module 130 may change an inside thereof into either a vacuum environment or an atmospheric pressure environment using a gate valve. The buffer module 130 may change the inside thereof into an environment identical to or similar to an internal environment of the index module 120. When the first transport robot 122 loads the substrate into the buffer module 130 or the first transport robot 122 unloads the substrate from the buffer module 130, the buffer module 130 may perform the above function. The buffer module 130 may prevent an internal pressure state of the index module 120 from changing.

The buffer module 130 may change the inside thereof into an environment identical or similar to an internal environment of the transfer module 140. When the second transport robot 142 loads the substrate into the buffer module 130 or the second transport robot 142 unloads the substrate from the buffer module 130, the buffer module 130 may perform the above function. The buffer module 130 may prevent an internal pressure state of the transfer module 140 from changing. As will be described later, the second transport robot 142 may be constructed within the transfer module 140.

The transfer module 140 may be disposed between the buffer module 130 and the process processing module 150. The transfer module 140 may be provided as an interface for substrate transfer between the buffer module 130 and the process processing module 150. The transfer module 140 may include a second module housing 141 and the second transport robot 142. The second module housing 141 may have a vacuum environment in an inner space thereof. The second transport robot 142 may be disposed within the second module housing 141 and may transport the substrate in the vacuum environment. The second transport robot 142 may include a single second transport robot or a plurality of second transport robots disposed within the second module housing 141.

The transfer module 140 may be connected to each of the substrate treating apparatuses 150a, 150b, . . . , 150n. The second module housing 141 may include a plurality of sides, and the second transport robot 142 may be configured to freely pivot around each of the sides of the second module housing 141 so that the second transport robot 142 may load the substrate into or unload the substrate from each of the substrate treating apparatuses 150a, 150b, . . . , 150n.

Each of the substrate treating apparatuses 150a, 150b, . . . , 150n may treat the non-treated substrate when the non-treated substrate has been provided thereto through the transfer module 140. Each of the substrate treating apparatuses 150a, 150b, . . . , 150n may provide the treated substrate to the transfer module 140.

The semiconductor manufacturing equipment 100 may be formed in a cluster platform structure. Referring to FIG. 1, the plurality of substrate treating apparatus 150a, 150b, . . . , 150n may be arranged in the cluster platform structure around the transfer module 140. However, the present disclosure is not limited thereto, and the semiconductor manufacturing equipment 100 may be formed in a quad platform structure. Referring to FIG. 2, the plurality of substrate treating apparatus 150a, 150b, . . . , 150n may be arranged in the quad platform structure around the transfer module 140. Alternatively, the semiconductor manufacturing equipment 100 may be formed in an in-line platform structure. Referring to FIG. 3, the plurality of substrate treating apparatus 150a, 150b, . . . , 150n may be arranged in the in-line platform structure around the transfer module 140 as shown in the example of FIG. 3, in which two arrangements of the substrate treating apparatuses may be respectively disposed on opposite sides of the transfer module 140, and the different substrate treating apparatuses in the two arrangements may face each other in a corresponding manner with each other, and each of the two arrangements may extend along a straight line extending in the second direction D2.

Although not shown in FIG. 1 to FIG. 3, the semiconductor manufacturing equipment 100 may further include a control device. The control device may control an operation of each of the modules constituting the semiconductor manufacturing equipment 100. For example, the control device may control the substrate transport operation of each of the transport robots 122 and 142, control the internal environmental change of each of the load lock chambers 130a and 130b, and control an overall substrate treatment process of each of the substrate treating apparatuses 150a, 150b, . . . , 150n.

The control device may include a processor that executes control of each of the components constituting the semiconductor manufacturing equipment 100, a network device over which the components communicate with each other in a wired manner or wirelessly, one or more instructions related to a function or an operation for controlling each of the components, a memory means that stores therein treating recipes including instructions or various data. The control device may further include a user interface including an input means (e.g., a touch screen or keyboard) for an operator to perform command input manipulation to manage the semiconductor manufacturing equipment 100, and an output means (e.g., a display monitor) for visualizing and displaying the operating status of the semiconductor manufacturing equipment 100. The control device may be embodied as a computing device for data processing and analysis or command transmission.

The instructions may be provided in a form of a computer program or an application. The computer program may be stored in a computer-readable recording medium containing one or more instructions. The instructions may include codes generated by a compiler, or codes that may be executed by an interpreter. The memory means may be embodied as one or more storage media selected from flash memory, HDD, SSD, card type memory, RAM, SRAM, ROM, EEPROM, PROM, magnetic memory, magnetic disk, or optical disk.

The substrate treating apparatus 150a is described. The substrate treating apparatus 150a may treat the substrate using one of the etching process, the cleaning process, the deposition process, and the ion implantation process. Hereinafter, a case where the substrate treating apparatus 150a treats the substrate using the etching process will be described. However, the present embodiment is not limited thereto, and a following description may be equally applied to a case where the substrate treating apparatus 150a treats the substrate using one of the cleaning process, the deposition process, and the ion implantation process.

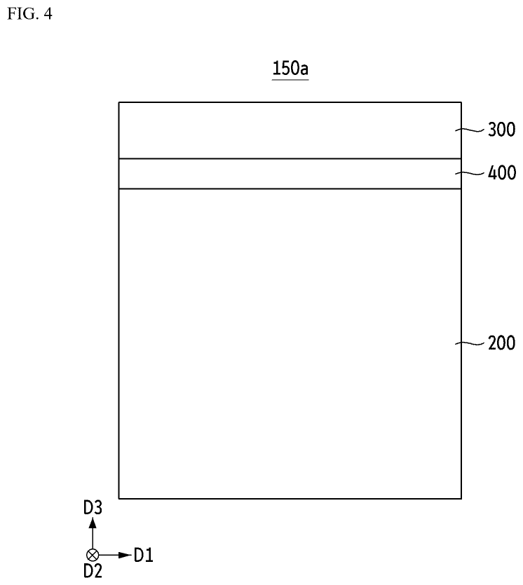

FIG. 4 illustrates an internal structure of the substrate treating apparatus of some embodiments of the present disclosure. Referring to FIG. 4, the substrate treating apparatus 150a may be configured to include a process chamber 200, a magnetic field generator 300, and a magnetic field mask 400.

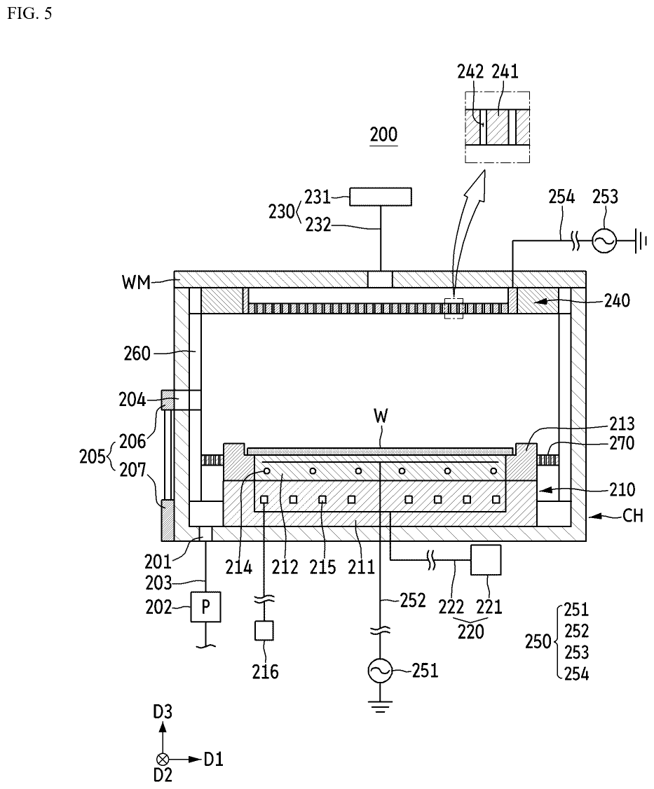

The process chamber 200 may treat the substrate using plasma. For example, the process chamber 200 may treat the substrate in a vacuum environment. FIG. 5 illustrates an internal structure of a process chamber constituting a substrate treating apparatus of some embodiments of the present disclosure. Referring to FIG. 5, the process chamber 200 may be configured to include a chamber housing CH, a substrate support unit 210, a cleaning gas supply unit 220, a process gas supply unit 230, a showerhead unit 240, a plasma generating unit 250 (i.e., a plasma generation unit), a liner unit 260, a baffle unit 270, and a window module WM.

The chamber housing CH provides a space where a process for treating the substrate W using plasma, i.e., a plasma process, is performed. The chamber housing CH may be made of alumite having an anodic oxide film formed on its surface, and an inner space thereof may be configured to be airtight. The chamber housing CH may be provided in a cylindrical shape. However, embodiments of the present disclosure are not limited thereto and the chamber housing CH may be provided in other shapes. The chamber housing CH may have an exhaust hole 201 defined in a bottom thereof.

The exhaust hole 201 may be connected to an exhaust line 203 equipped with a pump 202. The exhaust hole 201 may discharge reaction byproducts generated during the plasma process and gases remaining inside the chamber housing CH to the outside out of the chamber housing CH through the exhaust line 203. For the discharge of the inner space of the chamber housing CH, the pressure of the inner space of the chamber housing CH may be lowered.

An opening 204 may extend through a side wall of the chamber housing CH. The opening 204 may act as a passage through which the substrate W enters and exits the inside of the chamber housing CH. The opening 204 may be configured to be automatically opened and closed by, for example, a door assembly 205.

The door assembly 205 may be configured to include an outer door 206 and a door driver 207. The outer door 206 may open and close the opening 204 while being disposed on an outer wall of the chamber housing CH. The outer door 206 may be moved in the height direction D3 of the process chamber 200 under control of the door driver 207. The door driver 207 may operate using at least one element selected from a motor, a hydraulic cylinder, and a pneumatic cylinder.

The substrate support unit 210 is installed in a lower area of the inner space of the chamber housing CH. The substrate support unit 210 may hold and support the substrate W using an electrostatic force. For example, the substrate support unit 210 may be embodied as an electrostatic chuck (ESC). However, the present disclosure is not limited thereto, and the substrate support unit 210 may support the substrate W thereon using various other schemes such as vacuum and mechanical clamping.

When the substrate support unit 210 is embodied as the electrostatic chuck (ESC), the substrate support unit 210 may be configured to include a base plate 211 and a dielectric layer 212. The dielectric layer 212 may be disposed on the base plate 211 and may hold and support the substrate W that is placed thereon. The base plate 211 may be made of a material having excellent corrosion resistance and heat resistance. For example, the base plate 211 may be embodied as an aluminum body. A conductor layer instead of the dielectric layer 212 may be formed on the base plate 211. For example, the dielectric layer 212 may be made of ceramic.

Although not shown in FIG. 5, the substrate support unit 210 may be configured to further include a bonding layer. The bonding layer may bond the base plate 211 and the dielectric layer 212 to each other. The bonding layer may include, for example, a polymer.

A ring structure 213 is provided to surround an outer edge area of the dielectric layer 212. The ring structure 213 may serve to concentrate ions on the substrate W when the plasma process is performed inside the chamber housing CH. The ring structure 213 may be made of silicon. The ring structure 213 may be embodied, for example, as a focus ring. The focus ring in plasma etch equipment may enhance the uniformity and precision of the etching process by controlling the electric field and plasma distribution near the substrate.

Although not shown in FIG. 5, the ring structure 213 may further include an edge ring. The edge ring may be provided under or an outer side of the focus ring. The edge ring may serve to prevent a side surface of the dielectric layer 212 from being damaged by plasma. The edge ring may be made of an insulating material. For example, the edge ring may be made of ceramic or quartz.

A heating member 214 and a cooling member 215 are provided to maintain the substrate W at a process temperature when the substrate treating process is performed inside the chamber housing CH. The heating member 214 may be installed inside the dielectric layer 212 and may be embodied as a heating wire. The cooling member 215 may be installed inside the base plate 211 and may be embodied as a cooling pipe through which a coolant flows. A cooling device or a chiller 216 may supply the coolant to the cooling member 215. The cooling device 216 may use cooling water as the coolant. However, embodiments of the present disclosure are not limited thereto and helium (He) gas may be used as the coolant. Alternatively, the cooling device 216 may use both the cooling water and helium gas as the coolant. In one example, the heating member 214 may not be disposed inside the substrate support unit 210.

The cleaning gas supply unit 220 provides a cleaning gas onto the dielectric layer 212 or the ring structure 213 to remove foreign substances remaining on the dielectric layer 212 or the ring structure 213. For example, the cleaning gas supply unit 220 may provide nitrogen (N₂) gas as the cleaning gas.

The cleaning gas supply unit 220 may include a cleaning gas supply source 221 and a cleaning gas supply pipe 222. The cleaning gas supply pipe 222 may be connected to a space between the dielectric layer 212 and the ring structure 213. The cleaning gas supplied from the cleaning gas supply source 221 may flow to the space between the dielectric layer 212 and the ring structure 213 through the cleaning gas supply pipe 222 to remove the foreign substances remaining on an edge portion of the dielectric layer 212 or an upper portion of the ring structure 213.

The process gas supply unit 230 provides process gas to the inner space of the chamber housing CH. The process gas supply unit 230 may provide process gas to the inner space of the chamber housing CH through a hole extending through an upper cover, that is, the window module WM of the chamber housing CH. However, the present disclosure is not limited thereto, and the process gas supply unit 230 may provide the process gas to the inner space of the chamber housing CH through a hole extending through a side wall of the chamber housing CH.

The process gas supply unit 230 may include a process gas supply source 231 and a process gas supply pipe 232. The process gas supply source 231 may provide a gas used to treat the substrate W as the process gas. The process gas supply source 231 may be provided as a single process gas supply source in the process chamber 200. However, the present disclosure is not limited thereto and the process chamber 200 may include a plurality of process gas supply sources. In a case where the process chamber 200 includes the plurality of process gas supply sources 231, the plurality of process gas supply sources 231 may provide the same type of the process gas. However, the present disclosure is not limited thereto and the plurality of process gas supply sources 231 may provide different types of process gases.

The showerhead unit 240 sprays the process gas provided from the process gas supply source 231 to an entire area of the substrate W placed in the inner space of the chamber housing CH. The showerhead unit 240 may be connected to the process gas supply source 231 via the process gas supply pipe 232.

The showerhead unit 240 may be disposed in the inner space of the chamber housing CH and may include a showerhead body 241 and a plurality of gas feeding holes 242. The showerhead body 241 may be made of silicon. However, embodiments of the present disclosure are not limited thereto and the showerhead body 241 may be made of metal. The plurality of gas feeding holes 242 may extend through a surface of the showerhead body 241 in the vertical direction D3. The plurality of gas feeding holes 242 may be spaced apart from each other by a predetermined spacing and may extend through the showerhead body 241. The plurality of gas feeding holes 242 may uniformly inject the process gas to the entire area of the substrate W.

The showerhead unit 240 may be installed within the chamber housing CH so as to face the substrate support unit 210 in the vertical direction D3. The showerhead unit 240 may be constructed to have a diameter larger than a diameter of the dielectric layer 212. However, the present disclosure is not limited thereto. The showerhead unit 240 may be constructed to have the diameter equal to the diameter of the dielectric layer 212. The showerhead unit 240 may be made of silicon. However, the present disclosure is not limited thereto and the showerhead unit 240 may be made of metal.

Although not shown in FIG. 5, the showerhead unit 240 may be divided into a plurality of modules. For example, the showerhead unit 240 may be divided into three modules including a first head module, a second head module, and a third head module. The first head module may be disposed at a position corresponding to or overlapping a center area of the substrate W. The second head module may be disposed to surround an outer edge of the first head module. The second head module may be disposed at a position corresponding to or overlapping a middle area of the substrate W. The third head module may be disposed to surround an outer edge of the second head module. The third head module may be disposed at a position corresponding to or overlapping an edge area of the substrate W.

The plasma generation unit 250 may generate plasma from gas remaining in a discharge space. The discharge space may be embodied as a portion of the inner space of the chamber housing CH defined between the showerhead unit 240 and the window module WM. Alternatively, the discharge space may be a space defined between the substrate support unit 210 and the showerhead unit 240. When the discharge space is a space defined between the substrate support unit 210 and the showerhead unit 240, the discharge space may be divided into a plasma area and a process area. The plasma area may be positioned on top of the process area.

The plasma generation unit 250 may generate the plasma in the discharge space using a CCP (Capacitively Coupled Plasma) source. For example, the plasma generation unit 250 may generate the plasma in the discharge space using the substrate support unit 210 and the showerhead unit 240 as a lower electrode and an upper electrode, respectively.

However, the present embodiment is not limited thereto. The plasma generation unit 250 may generate the plasma in the discharge space using an ICP (Inductively Coupled Plasma) source. The process chamber 200 may further include an antenna unit. The plasma generating unit 250 may generate plasma in the discharge space using the substrate support unit 210 and the antenna unit as the lower electrode and the upper electrode, respectively. A case where the plasma generating unit 250 employs the ICP source will be described later.

The plasma generating unit 250 may be configured to include a first high-frequency power source 251, a first transmission line 252, a second high-frequency power source 253, and a second transmission line 254. When the plasma generating unit 250 includes the first high-frequency power source 251 and the second high-frequency power source 253, multi-frequency may be applied to the process chamber 200.

The first high-frequency power source 251 may apply a radio frequency (RF) power to the lower electrode. The first high-frequency power source 251 may serve as a plasma source that generates plasma within the chamber housing CH. However, the present disclosure is not limited thereto. The first high-frequency power source 251 together with the second high-frequency power source 253 may serve to control the characteristics of the plasma within the chamber housing CH.

The first high-frequency power source 251 may include a plurality of first high-frequency power sources included within the process chamber 200. In this case, the plasma generation unit 250 may include a first matching network electrically connected to each of the first high-frequency power sources. When RF powers of different magnitudes are input from the plurality of first high-frequency power sources thereto, the first matching network may serve to match the RF powers of different magnitudes with each other and apply the matched RF powers to the lower electrode.

The first transmission line 252 may connect the lower electrode to the ground (GND). The first high-frequency power source 251 may be installed on the first transmission line 252. However, the present disclosure is not limited thereto, and the first transmission line 252 may connect the lower electrode and the first high-frequency power source 251 to each other. For example, the first transmission line 252 may be embodied as an RF rod.

The second high-frequency power source 253 applies the RF power to the upper electrode. The second high-frequency power source 253 may serve to control the characteristics of the plasma within the chamber housing CH. For example, the second high-frequency power source 253 may serve to control an ion bombardment energy of ions within the chamber housing CH.

The second high-frequency power source 253 may include a plurality of second high-frequency power sources included within the process chamber 200. In this case, the plasma generation unit 250 may include a second matching network electrically connected to each of the second high-frequency power sources. When RF powers of different magnitudes are input from the plurality of second high-frequency power sources thereto, the second matching network may serve to match the RF powers of different magnitudes with each other and apply the matched RF powers to the upper electrode. In an embodiment, the second high-frequency power source 253 may serve to generate plasma in the discharge space, and the first high-frequency power source 251 may serve to control a bias voltage or an electric field of a plasma sheath region on the wafer, which determines an ion bombardment energy and an angular distribution of ions travelling toward the wafer.

The second transmission line 254 connects the upper electrode to GND. The second high-frequency power source 253 may be installed on the second transmission line 254.

The liner unit 260 is also defined as a wall liner and serves to protect the inside of the chamber housing CH from arc discharge generated during the process of exciting the process gas or impurities generated during the substrate treating process. The liner unit 260 may be formed to cover an inner wall of the chamber housing CH.

The baffle unit 270 serves to exhaust process byproducts or unreacted gases of the plasma inside the chamber housing CH to the outside. The baffle unit 270 may be installed in the space between the substrate support unit 210 and the inner wall (or the liner unit 260) of the chamber housing CH, and may be installed adjacent to the exhaust hole 201. The baffle unit 270 may be provided in an annular ring shape and may be disposed between the substrate support unit 210 and the inner wall of the chamber housing CH.

The baffle unit 270 may include a body and a plurality of slot holes extending through the body in the vertical direction D3 to control flow of the process gas within the chamber housing CH. The baffle unit 270 may be made of a material having etching resistance to minimize damage thereto or deformation thereof by radicals in the inner space of the chamber housing CH where the plasma is generated. For example, the baffle unit 270 may include quartz.

The window module WM serves as the upper cover of the chamber housing CH that seals the inner space of the chamber housing CH. The window module WM may be configured to be removable from the chamber housing CH. However, embodiments of the present disclosure are not limited thereto, and the window module WM may be integrated into the chamber housing CH. For example, the window module WM and the chamber housing CH may be formed of a unitary body. The window module WM may be formed as a dielectric window made of an insulating material. For example, the window module WM may be made of alumina. The window module WM may include a coating film on a surface thereof to suppress the generation of particles when the plasma process is performed in the inner space of the chamber housing CH.

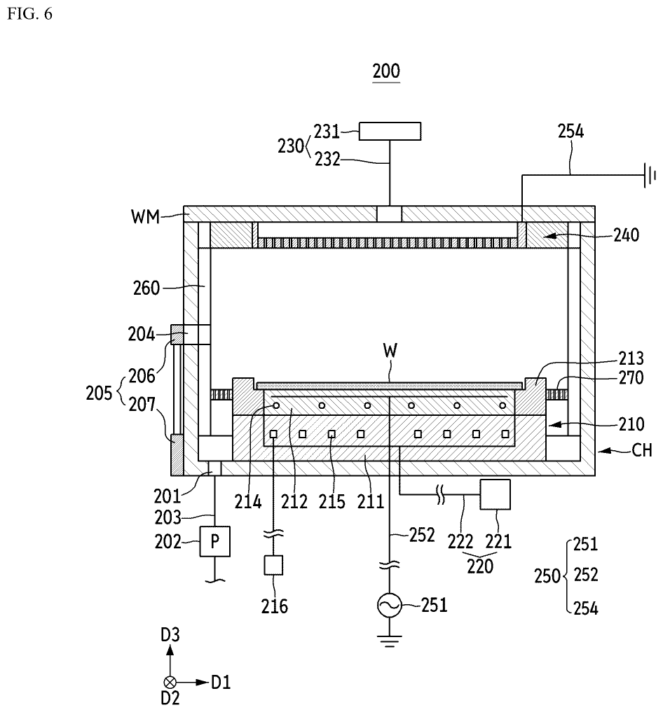

In the process chamber 200, the showerhead unit 240 may be provided as the upper electrode. The upper electrode may be connected to the high-frequency power source, or may be connected to the GND. Referring to FIG. 6, when the upper electrode is connected to the GND, the plasma generating unit 250 may include the first high-frequency power source 251, the first transmission line 252, and the second transmission line 254. The second transmission line 254 may be connected to the GND. The plasma generating unit 250 may not include the second high-frequency power source 253. FIG. 6 is a second example diagram illustrating an internal structure of a process chamber constituting a substrate treating apparatus of some embodiments of the present disclosure.

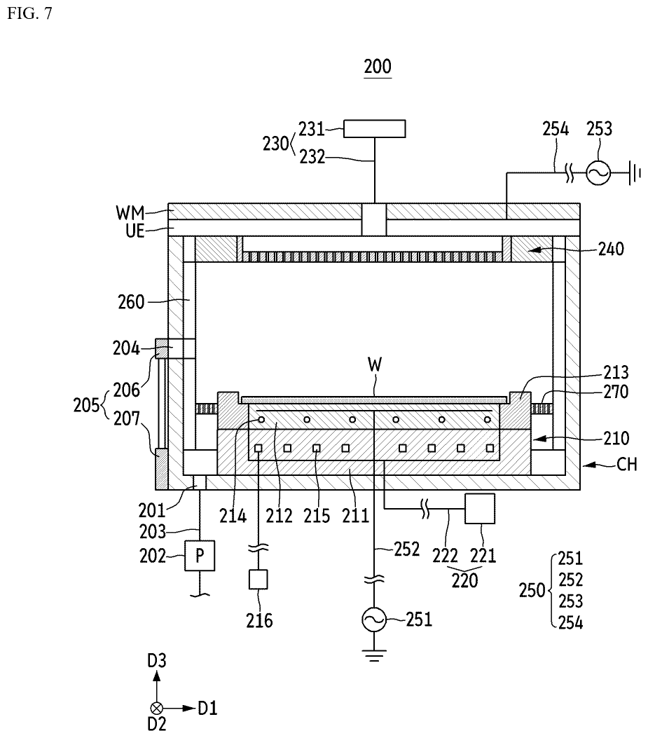

In the process chamber 200, the showerhead unit 240 may not be provided as the upper electrode. Referring to FIG. 7, an upper electrode UE may be disposed under the window module WM. The upper electrode UE may be disposed between the window module WM and the showerhead unit 240. The upper electrode UE may be connected to the high-frequency power source. In this case, the plasma generating unit 250 may include the first high-frequency power source 251, the first transmission line 252, the second high-frequency power source 253, and the second transmission line 254. The present disclosure is not limited thereto. In an embodiment, the upper electrode UE may be connected to the GND. In this case, the plasma generating unit 250 may include the first high-frequency power source 251, the first transmission line 252, and the second transmission line 254. The plasma generating unit 250 may not include the second high-frequency power source 253. FIG. 7 illustrates an internal structure of a process chamber constituting a substrate treating apparatus of some embodiments of the present disclosure.

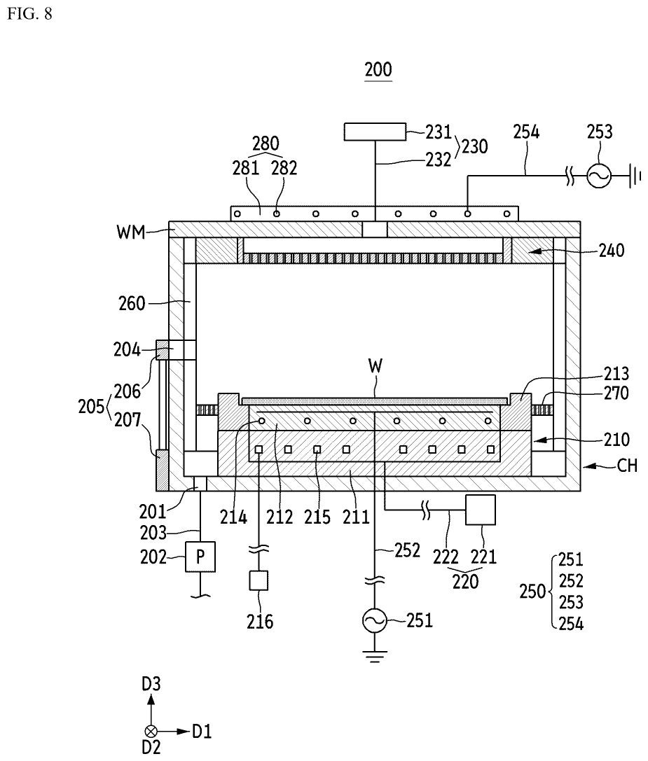

Descriptions are given of a case where the plasma generating unit 250 employs the ICP source. FIG. 8 illustrates an internal structure of a process chamber constituting a substrate treating apparatus of some embodiments of the present disclosure. In following descriptions, contents duplicate with those described above with reference to FIG. 5 are not described, and the following descriptions are mainly based on differences therebetween.

The antenna unit 280 generates a magnetic field and an electric field inside the chamber housing CH to excite the process gas into plasma. The antenna unit 280 may operate using the RF power supplied from the second high-frequency power source 253. The antenna unit 280 may be disposed on top of the chamber housing CH. For example, the antenna unit 280 may be disposed on the window module WM. However, the present disclosure is not limited thereto, and the antenna unit 280 may be disposed on the side wall of the chamber housing CH.

The antenna unit 280 may include a body 281, and an antenna 282 inside or on a surface of the body 281. The antenna 282 may be formed in a closed loop shape using a coil. The antenna 282 may be formed in a spiral shape or other various shapes along a width direction D1 of the chamber housing CH.

The antenna unit 280 may be formed to have a planar structure. However, the present disclosure is not limited thereto, and the antenna unit 280 may be formed to have a cylindrical structure. When the antenna unit 280 is formed to have the planar structure, the antennal unit may be disposed on top of the chamber housing CH. When the antenna unit 280 is formed to have the cylindrical structure, the antenna unit 280 may be disposed to surround the outer wall of the chamber housing CH.

When the process chamber 200 includes the antenna unit 280, the second transmission line 254 may be connected to the antenna 282 of the antenna unit 280. The second high-frequency power source 253 may apply RF power to the antenna 282 of the antenna unit 280. When the process chamber 200 does not include the antenna unit 280, the second transmission line 254 may be connected to the showerhead body 241 of the showerhead unit 240. The second high-frequency power source 253 may apply RF power to the showerhead body 241 of the showerhead unit 240.

Referring again to FIG. 4, the description will be made.

The magnetic field generator 300 may generate a magnetic field (i.e., a first magnetic field). The magnetic field generator 300 may be disposed on the process chamber 200. The magnetic field generator 300 may generate a magnetic field and provide the magnetic field toward the process chamber 200. For example, the magnetic field generator 300 may apply a magnetic field to the process chamber 200 while the process chamber 200 treats the substrate W.

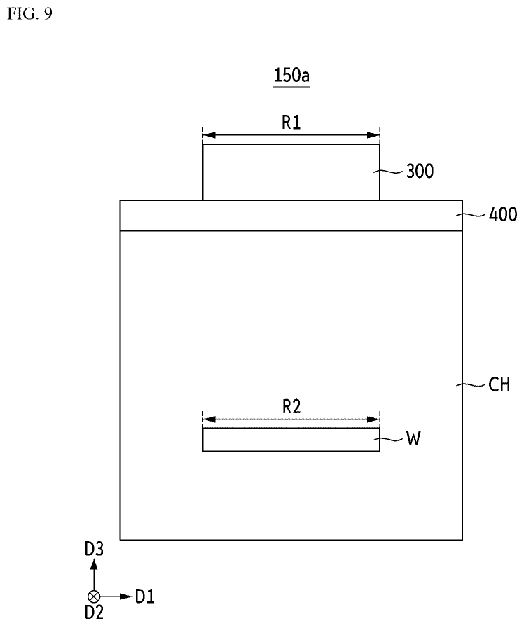

The magnetic field generator 300 may be formed on an entirety of an upper area of the process chamber 200. However, the present disclosure is not limited thereto, and the magnetic field generator 300 may be formed on an upper partial area of the process chamber 200. The magnetic field generator 300 may be formed on a center of the upper area of the chamber housing CH. FIG. 9 illustrates an internal structure of a substrate treating apparatus of some embodiments of the present disclosure. Referring to FIG. 9, the magnetic field generator 300 may be provided in a cylindrical shape. An area R1 where the magnetic field generator 300 is seated may correspond to an area R2 where the substrate W is located within the process chamber 200. The area R1 where the magnetic field generator 300 is seated may overlap in the third direction DR the area R2 where the substrate W is located.

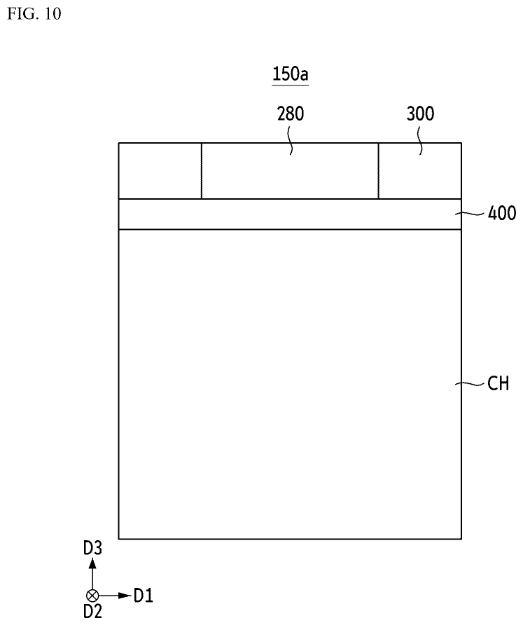

The magnetic field generator 300 may be formed on an upper edge area of the chamber housing CH. FIG. 10 illustrates an internal structure of a substrate treating apparatus of some embodiments of the present disclosure. Referring to FIG. 10, the antenna unit 280 may be formed in the upper center area of the chamber housing CH, and the magnetic field generator 300 may be formed in the upper edge area of the chamber housing CH. The antenna unit 280 may be provided in a cylindrical shape, and the magnetic field generator 300 may be provided in a ring shape. The magnetic field generator 300 may be positioned at the same level as that of the antenna unit 280 in the third direction D3.

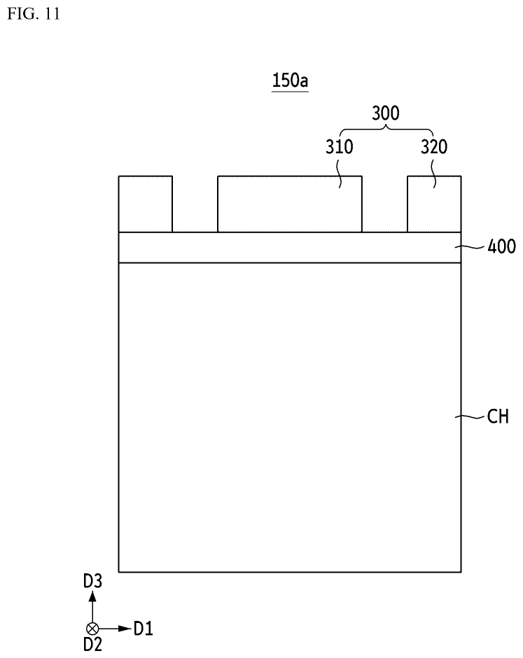

The magnetic field generator 300 may include a single magnetic field generator or a plurality of magnetic field generators. FIG. 11 illustrates an internal structure of a substrate treating apparatus of some embodiments of the present disclosure. Referring to FIG. 11, the magnetic field generator 300 may include a first magnetic field generating unit 310 and a second magnetic field generating unit 320. The first magnetic field generating unit 310 may be disposed on a center of the upper area of the chamber housing CH. The second magnetic field generating unit 320 may be disposed on the upper edge area of the chamber housing CH. The first magnetic field generating unit 310 may be provided in a cylindrical shape, and the second magnetic field generating unit 320 may be provided in a ring shape.

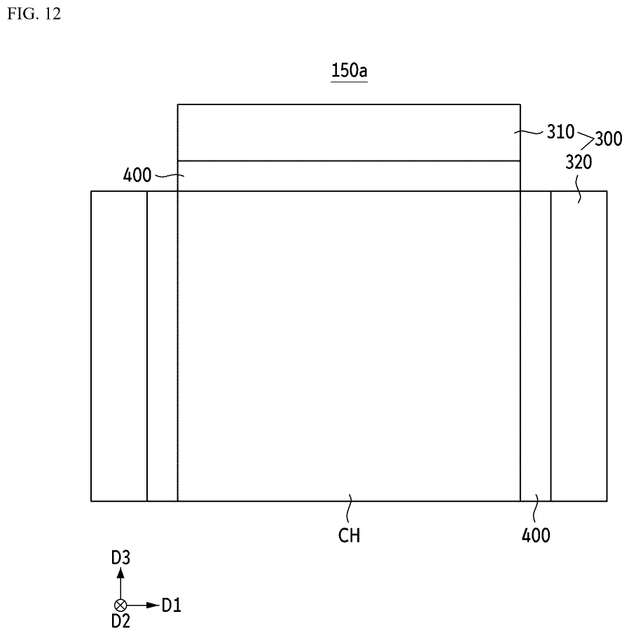

The magnetic field generator 300 may be disposed not only on the upper area of the chamber housing CH, but also on a side area of the chamber housing CH or a lower area of the chamber housing CH. FIG. 12 illustrates an internal structure of a substrate treating apparatus of some embodiments of the present disclosure. Referring to FIG. 12, the first magnetic field generating unit 310 may be disposed on the upper area of the chamber housing CH. The first magnetic field generating unit 310 may be formed on the entire upper area of the chamber housing CH, or may be formed on the upper partial area of the chamber housing CH. The first magnetic field generating unit 310 may be provided as a single unit, or may be provided as a plurality of units. The second magnetic field generating unit 320 may be disposed on the side area of the chamber housing CH. The second magnetic field generating unit 320 may be formed on an entirety of the side area of the chamber housing CH, or may be formed on a portion of the side area of the chamber housing CH. The second magnetic field generating unit 320 may be provided as a single unit, or may be provided as a plurality of units.

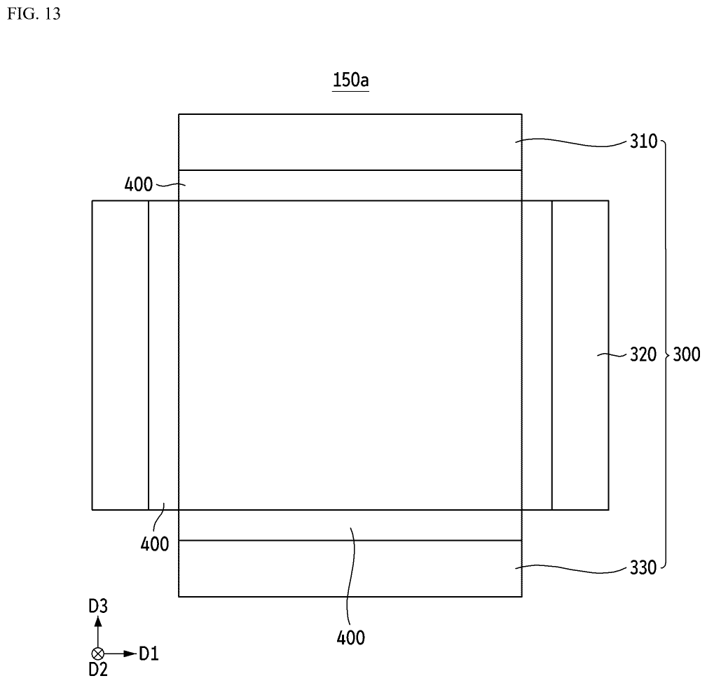

FIG. 13 illustrates an internal structure of a substrate treating apparatus of some embodiments of the present disclosure. Referring to FIG. 13, the magnetic field generator 300 may include a first magnetic field generating unit 310, a second magnetic field generating unit 320, and a third magnetic field generating unit 330. Each of the first magnetic field generating unit 310 and the third magnetic field generating unit 330 may be provided in a cylindrical shape. The second magnetic field generating unit 320 may be provided in a ring shape. The third magnetic field generating unit 330 may be disposed on the lower area of the chamber housing CH. The third magnetic field generating unit 330 may be formed on the entire lower area of the chamber housing CH, or may be formed on the lower partial area of the chamber housing CH. The third magnetic field generating unit 330 may be provided as a single unit, or may be provided as a plurality of units.

FIG. 4 illustrates a case where the magnetic field generator 300 is formed on the upper area of the chamber housing CH. FIG. 12 illustrates a case where the magnetic field generator 300 is formed on the upper area and the side area of the chamber housing CH. FIG. 13 illustrates a case where the magnetic field generator 300 is formed on the upper area, the side area, and the lower area of the chamber housing CH. However, the present disclosure is not limited thereto, and the magnetic field generator 300 may be formed on the side area and the lower area of the chamber housing CH. Alternatively, the magnetic field generator 300 may be formed only on one of the side area and the lower area of the chamber housing CH.

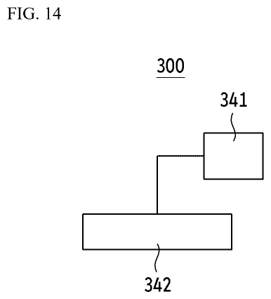

FIG. 14 is an example diagram illustrating an internal structure of a magnetic field generator constituting a substrate treating apparatus of some embodiments of the present disclosure. Referring to FIG. 14, the magnetic field generator 300 may include a first power source 341 and a magnetic body 342. The first power source 341 may provide power to the magnetic body 342. The magnetic body 342 may generate a magnetic field based on the power provided by the first power source 341. For example, the magnetic body 342 may be provided as an electromagnet. The magnetic body 342 may be provided as a single magnetic body or may be provided as a plurality of magnetic bodies. When the magnetic body 342 is provided as the plurality of magnetic bodies, the first power source 341 may be connected to the magnetic body 342 in one-to-many corresponding manner. For example, the first power source 341 may be connected to each of the plurality of magnetic bodies. However, the present disclosure is not limited to this, and the first power source 341 may be connected to the magnetic body 342 in one-to-one corresponding manner. When the magnetic body 342 is provided as the plurality of magnetic bodies, the first power source 341 may be provided as a plurality of power sources. For example, each of the power sources may be connected to a corresponding magnetic body of the plurality of magnetic bodies, and the number of the first power sources 341 may be equal to the number of the magnetic bodies 342.

In one example, the magnetic body 342 may be provided as a permanent magnet. Alternatively, the magnetic body 342 may be provided as a combination of a permanent magnet and an electromagnet. When the magnetic body 342 is provided as the plurality of magnetic bodies, some thereof may be provided as electromagnets, and others thereof may be provided as permanent magnets. When the magnetic body 342 is provided as a permanent magnet, the magnetic field generator 300 may not include the first power source 341.

The present disclosure will be described with reference to FIG. 4.

The magnetic field mask 400 may apply a magnetic field (i.e., a second magnetic field) and control the magnetic field generated in the process chamber 200 by interference. The magnetic field mask 400 may control the magnetic field generated by the magnetic field generator 300. The magnetic field mask 400 may be disposed in a space between the process chamber 200 and the magnetic field generator 300. The magnetic field mask 400 may contact the magnetic field generator 300. The present disclosure is not limited thereto. In an embodiment, the magnetic field mask 400 may be spaced apart from the magnetic field generator 300. The substrate treating apparatus 150a may control the plasma generated in the process chamber 200 using the magnetic field mask 400. The substrate treating apparatus 150a may be applied to a high aspect ratio contact (HARC) process.

In the process chamber 200, one of the representative types of defects is the problem in which the substrate W is not etched straightly in the vertical direction D3 but in a bent manner. The incident angle of the ions may be determined according to a shape of the bulk plasma. Since the initial incident angle of the ions is determined as the direction perpendicular to the plasma sheath, a uniform sheath thickness should be formed directly on top of the substrate W so that the ions may be irradiated straightly without being tilted. In order to increase the yield of the semiconductor, it is desirable to secure plasma density uniformity through various controls.

When performing the HARC etching process using the process chamber 200, the magnetic field generator 300 may be used to generate the magnetic field to improve a slope critical dimension (SCD) distribution of etched features on a wafer, and the plasma may be controlled accordingly. The SCD refers to the variation in the width or dimensions of an etched feature caused by the slope or angle of the sidewalls. The SCD measures the difference in feature dimensions between the top and bottom of an etched feature due to a non-ideal etching profile. For example, if a trench or hole is intended to have vertical sidewalls, deviations in the slope of these sidewalls result in differences between the dimensions at the top (mask opening) and the bottom (etched area). In the substrate treating apparatus using the CCP source, the magnetic field applied in the inside of the process chamber 200 may affect a direction of migration of electrons that generate plasma while reciprocating in the vertical direction D3 under the RF power, thereby changing the plasma density. In order to control the plasma density of a specific area in the process chamber 200, a magnetic field distribution should be supplied to the specific area. To this end, a scheme in which a plurality of magnetic field generating units are positioned at multiple locations may be used.

Hereinafter, the principle under which the magnetic field distribution affects the plasma density in the process chamber 200 is described. When the RF power is applied, electrons inside the process chamber 200 perform vertical reciprocating movement in a direction perpendicular to the substrate W in accordance with a RF cycle. In this process, when the electrons have an energy level higher than the ionization energy level of surrounding gas molecules before the electrons reach the upper electrode or the lower electrode and thus are annihilated due to the RF power, pressure condition, the electrons ionize the surrounding gas molecules such that the plasma is ignited.

With the RF power applied, when a magnetic field is applied to the inside of the process chamber 200, the electrons receive the Lorentz force such that the direction of movement of the electrons changes. In a cylindrical coordinate system (r, θ, z), when a semiconductor substrate or an electrode is oriented in a parallel manner to a r-θ plane, electrons mainly migrate vertically in a direction parallel to the z-axis in an environment where the RF power is applied to the process chamber 200. At this time, the r-directional magnetic field component Bᵣ may prevent electrons from spreading in the perpendicular direction with respect to the substrate, and the z-directional magnetic field component B_{z} may prevent electrons from spreading in a direction parallel with respect to the substrate. In particular, electrons move in a spiral manner due to the z-directional velocity components v_{z} and Bᵣ, and a path along which the electrons can move along and collide with the surrounding gas molecules before colliding with the upper or lower electrode outside the bulk plasma and being lost increases, thereby increasing the probability of collision. This spiral movement of the electrons may cause to increase the ionization percentage, thereby increasing the plasma density. In summary, when a desired Bᵣ distribution may be applied to the inside of the process chamber 200, the plasma density can be controlled in a desired direction.

In some embodiments, the magnetic field mask 400 may be disposed between the process chamber 200 and the magnetic field generator 300. Since a magnetic force line extends from the N pole to the S pole and thus does not extend in a straight line, it is not easy to predict or control the direction of the magnetic force line. However, the magnetic field mask 400 may control the magnetic field distribution. The magnetic field mask 400 may include a ferromagnetic material. The ferromagnetic material may be easily magnetized under a magnetic field atmosphere and interfere with the surrounding magnetic field distribution. The magnetic field components Bᵣ, B_{θ}, and B_{z} of the magnetic field generated by magnetic field generator 300 may change as the magnetic force line is bent due to the ferromagnetic material. When the magnetic field mask 400 includes the ferromagnetic material, the plasma may be controlled using the magnetic field interference effect between the magnetic field components Bᵣ, B_{θ}, and B_{z} of the magnetic field (i.e., the first magnetic field) magnetic field generator 300 and a magnetic field (i.e., a second magnetic field) of the magnetic field mask 400. The magnetic field mask 400 may include a magnetic material having a relative permeability greater than 1. For example, the magnetic field mask 400 may be made of ferrite, permalloy, or silicon steel. In the present disclosure, the magnetic field mask 400 embodied as a ferromagnetic structure may be used to control Bᵣ (R3), B_{θ} (R3), and B_{z} (R3), which represent magnetic components at a position (R3) in the process chamber 200. R3 represents a diameter of the process chamber 200.

Since the magnetic field mask 400 may be used to control all of the Bᵣ, B_{θ}, and B_{z} directions, the magnetic field component Br may allow the θ directional force to be applied to electrons moving up and down in the z direction, and the magnetic field component B_{θ} may allow the r directional force to be applied to electrons moving up and down in the z direction. In other words, the Bᵣ and B_{θ} components may respectively apply the θ and r directional forces to the electrons in the positive and negative directions according to an RF period, thereby improving the plasma density.

In the substrate treating apparatus using the ICP source applying an RF power, when the magnetic field generator applies the magnetic field, electrons inside the process chamber 200 perform a rotational movement in the θ direction opposite to the antenna current in accordance with the RF period of the RF power applied to the ICP source on a plane horizontal to the substrate W. According to the same principle, under the Lorenz force, Bᵣ and B_{z} may apply the z and r directional forces, respectively, to the electrons inside the process chamber 200 in the positive and negative directions in accordance with the RF period.

In summary, in the substrate treating apparatus using the CCP source, Bᵣ and B_{θ} magnetic field components may affect the plasma density. In the substrate treating apparatus using the ICP source, Bᵣ and B_{z} magnetic field components may affect the plasma density. According to the present disclosure, all of the Bᵣ, B_{θ}, and B_{z} magnetic field components may be controlled using the magnetic field mask 400, such that the effect of improving the plasma density may be obtained not only in the substrate treating apparatus using the CCP source but also in the substrate treating apparatus using the ICP source.

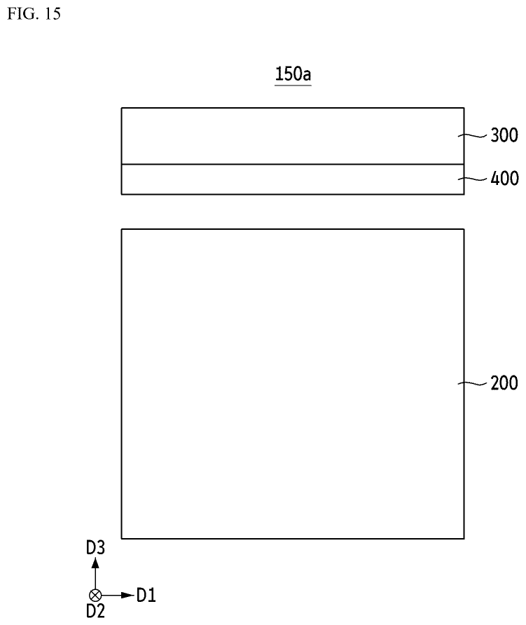

The magnetic field mask 400 may contact the process chamber 200. However, the present disclosure is not limited thereto, and the magnetic field mask 400 may be spaced apart from the process chamber 200 as illustrated in FIG. 15. FIG. 15 illustrates a magnetic field mask constituting a substrate treating apparatus of some embodiments of the present disclosure. When the magnetic field mask 400 contacts the process chamber 200, the substrate treating apparatus 150a may utilize the magnetic field mask 400 as a knob (Coarse Tuning Knob) with high sensitivity to control the magnetic field, in the process chamber 200, generated by the magnetic field generator 300. When the magnetic field mask 400 is spaced apart from the process chamber 200, the substrate treating apparatus 150a may utilize the magnetic field mask 400 as a knob (Fine Tuning Knob) with low sensitivity to control the magnetic field, in the process chamber 200, generated by the magnetic field generator 300. In this regard, sensitivity may mean influence on the magnetic field.

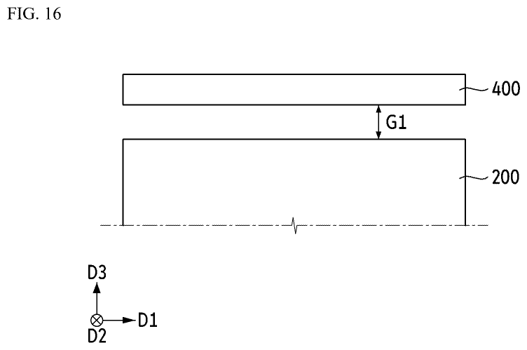

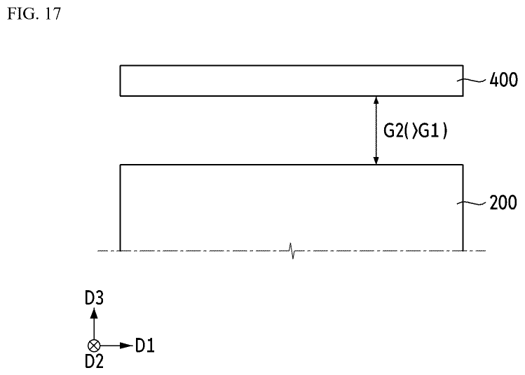

The magnetic field mask 400 may have a spacing thereof from the process chamber 200 varying depending on the sensitivity. FIG. 16 illustrates a magnetic field mask constituting a substrate treating apparatus of some embodiments of the present disclosure. FIG. 17 illustrates a magnetic field mask constituting a substrate treating apparatus of some embodiments of the present disclosure. Referring to FIG. 16, the spacing between the magnetic field mask 400 and the process chamber 200 may be a first distance G1. Referring to FIG. 17, the spacing between the magnetic field mask 400 and the process chamber 200 may be a second distance G2. The second distance G2 may have a larger value than the first distance G1. When the spacing is the first distance G1, the magnetic field mask 400 may be closer to the process chamber 200 than the magnetic field mask 400 may be when the spacing is the second distance G2. When the spacing is the second distance G2, the magnetic field mask 400 may be further away from the process chamber 200 than the magnetic field mask 400 may be when the spacing is the first distance G1. When the spacing is the first distance G1, the magnetic field mask 400 may be more suitable for use as a knob with high sensitivity than when the spacing is the second distance G2. When the spacing is the second distance G2, the magnetic field mask 400 may be more suitable for use as a knob with low sensitivity than when the spacing is the first distance G1.

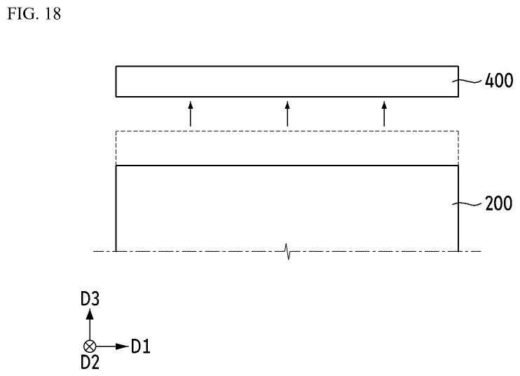

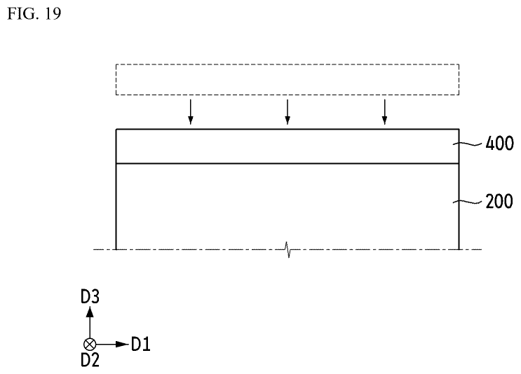

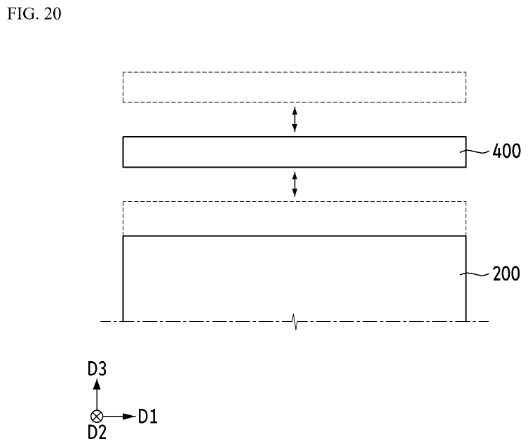

The magnetic field mask 400 may be fixed in its position on the process chamber 200. The magnetic field mask 400 may be fixed in position while contacting the top of the process chamber 200. In some embodiments, the magnetic field mask 400 may be fixed in position while being spaced apart from the top of the process chamber 200 by a certain spacing. In some embodiments, the magnetic field mask 400 may be fixed in position while the substrate W is being treated in the process chamber 200. However, the present disclosure is not limited thereto, and a position on the process chamber 200 at which the magnetic field mask 400 is positioned may change while the substrate W is being treated. FIG. 18 illustrates a magnetic field mask constituting a substrate treating apparatus of some embodiments of the present disclosure. FIG. 19 illustrates a magnetic field mask constituting a substrate treating apparatus of some embodiments of the present disclosure. FIG. 20 illustrates a magnetic field mask constituting a substrate treating apparatus of some embodiments of the present disclosure. Referring to FIG. 18, the spacing between the magnetic field mask 400 and the process chamber 200 may increase while the substrate W is being treated. Referring to FIG. 19, the spacing between the magnetic field mask 400 and the process chamber 200 may decrease while the substrate W is being treated. Referring to FIG. 20, the magnetic field mask 400 may be repeatedly closer to and further away from the process chamber 200 while the substrate W is being treated.

In one example, although not depicted in the drawings, the magnetic field mask 400 may be mounted within a non-magnetic structure. The magnetic field mask 400 may be spaced from the process chamber 200 and the magnetic field generator 300 via the non-magnetic structure. Furthermore, the magnetic field mask 400 may be positioned within the non-magnetic structure so as to be closer to the process chamber 200 or so as to be far away from the process chamber 200. Furthermore, the magnetic field mask 400 may be positioned in an inner space of the non-magnetic structure so that a distance between the magnetic field mask 400 and the process chamber 200 changes. The non-magnetic structure may include a non-magnetic material body. In an embodiment, the non-magnetic material body may include an aluminum body.

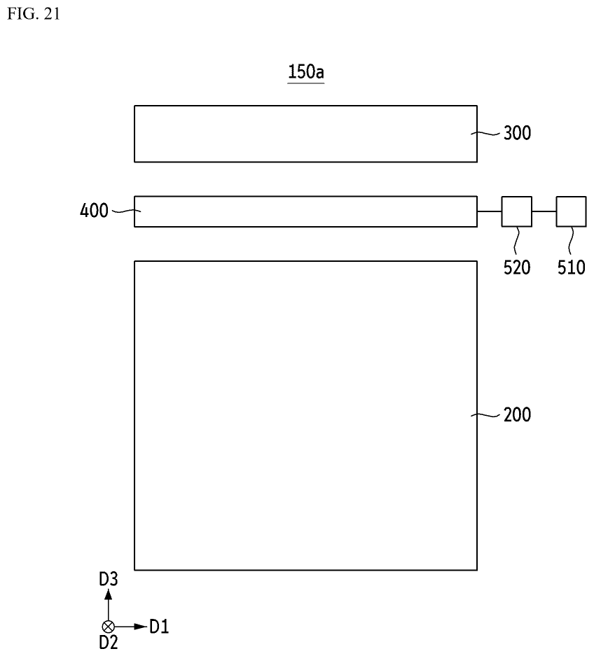

FIG. 21 illustrates a magnetic field mask constituting a substrate treating apparatus of some embodiments of the present disclosure. Referring to FIG. 21, when the position on the process chamber 200 at which the magnetic field mask 400 is positioned changes, the substrate treating apparatus 150a may further include a second power source 510 and a position adjuster 520. The second power source 510 may provide power to the position adjuster 520. The position adjuster 520 may change the position of the magnetic field mask 400 on the process chamber 200. The position adjuster 520 may include a motor. In an embodiment, the motor of the position adjuster 520 may include a linear motor moving the magnetic field mask 400 in the third direction D3. For example, the linear motor of the position adjuster 520 may move up the magnetic field mask 400 or move down the magnetic field mask 400.

The magnetic field mask 400 may include a pattern of a predetermined shape on its surface. As described above, the magnetic field mask 400 may control a ratio of the magnetic field components Bᵣ, B_{θ}, and B_{z} via selective magnetic field interference. For example, the pattern may control the distribution of the magnetic field component. The pattern may contribute to controlling the plasma density in a specific area within the process chamber 200.

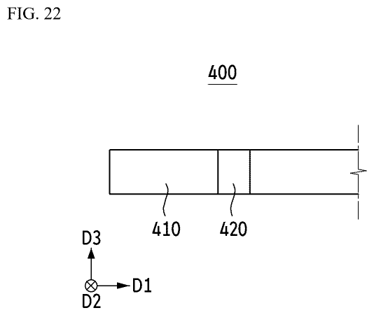

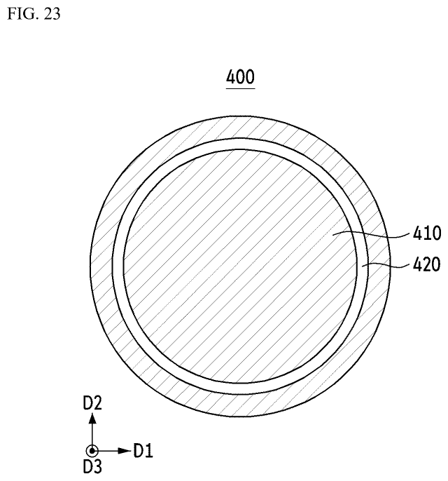

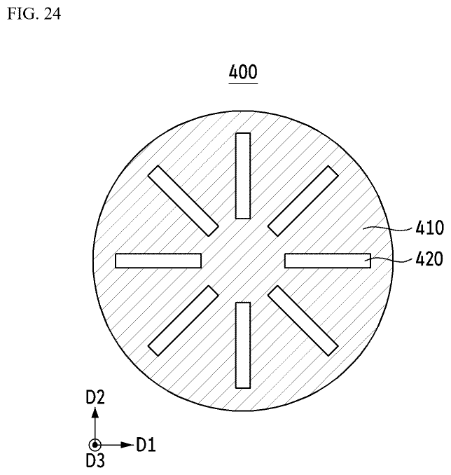

FIG. 22 illustrates a pattern in a magnetic field mask constituting a substrate treating apparatus of some embodiments of the present disclosure. FIG. 23 illustrates a pattern in a magnetic field mask constituting a substrate treating apparatus of some embodiments of the present disclosure. FIG. 24 illustrates a pattern in a magnetic field mask constituting a substrate treating apparatus of some embodiments of the present disclosure. Referring to FIG. 22, the magnetic field mask 400 may include a main body 410 and a slit 420 extending through the main body 410. The slit 420 may be formed in a structure equivalent to a hole. The slit 420 may include a single slit or a plurality of slits extending through the main body 410. The slit 420 may be provided in various shapes. For example, referring to FIG. 23, the slit 420 may extend in a ring-shaped structure and extend through the main body 410. Alternatively, referring to FIG. 24, the slit 420 may extend in a radial structure and extend through the main body 410. However, the structure of the slit 420 is not limited thereto, and may be variously modified.

The magnetic field mask 400 may be magnetized by the magnetic field generator 300. The magnetic field mask 400 may cause interference in the magnetic field distribution and change the distribution of the magnetic field component. The magnetic field mask 400 may increase a strength of a specific magnetic field component (e.g., the magnetic component Br when the slit 420 has the circular structure, and the magnetic component B_{θ} when the slit 420 has the radial structure) in the vertical direction near a boundary surface of the slit 420. For example, the ratio of the magnetic component Br of the magnetic field formed in the process chamber 200 may increase when a vertical magnetic component of the magnetic field mask 400 is arranged along the boundary of the slit 420 with the circular structure as shown in FIG. 23, and the ratio of the magnetic component B_{θ} of the magnetic field in the process chamber 200 may increase when a vertical magnetic component of the magnetic field mask 400 is arranged along the boundary of the slit 420 with the radial structure as shown in FIG. 24. The magnetic field mask 400 may contribute to controlling the plasma density in a specific area by utilizing the spacing, position, or pattern of the slit 420.

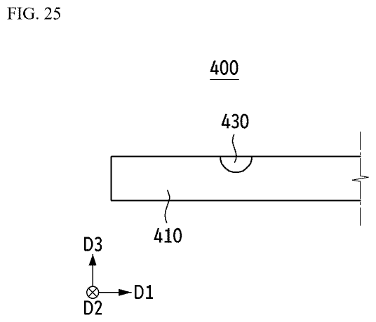

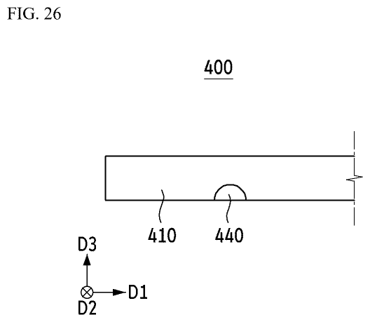

FIG. 25 illustrates a pattern in a magnetic field mask constituting a substrate treating apparatus of some embodiments of the present disclosure. FIG. 26 illustrates a pattern within a magnetic field mask constituting a substrate treating apparatus of some embodiments of the present disclosure. Referring to FIG. 25, the magnetic field mask 400 may have a first trench 430 defined at an upper surface of the main body 410. Referring to FIG. 26, the magnetic field mask 400 may have a second trench 440 defined at a lower surface of the main body 410. The first trench 430 and the second trench 440 may not extend through the main body 410. Each of the first trench 430 and the second trench 440 may be formed in a structure equivalent to a groove. Each of the first trench 430 and the second trench 440 may include a single trench or a plurality of trenches. Each of the first trench 430 and the second trench 440 may be provided in various shapes. For example, each of the first trench 430 and the second trench 440 may be formed in an annular structure. Alternatively, each of the first trench 430 and the second trench 440 may be formed in a radial structure.

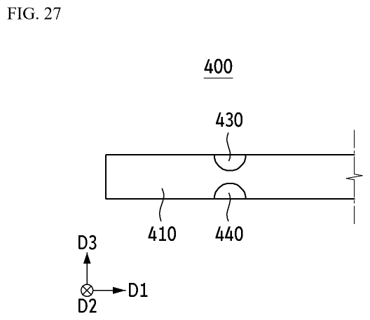

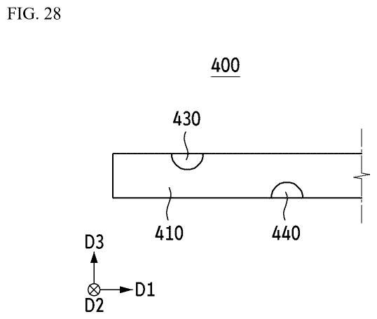

The magnetic field mask 400 may have a trench defined in each of the upper surface and the lower surface of the main body 410. FIG. 27 illustrates a pattern in a magnetic field mask constituting a substrate treating apparatus of some embodiments of the present disclosure. FIG. 28 illustrates a pattern within a magnetic field mask constituting a substrate treating apparatus of some embodiments of the present disclosure. Referring to FIG. 27, the magnetic field mask 400 may have the first trench 430 and the second trench 440. The first trench 430 and the second trench 440 may be formed at positions corresponding to each other in the third direction D3. The first trench 430 may overlap the second trench 440 in the third direction D3. The first trench 430 may entirely overlap the second trench 440, or may overlap partially with the second trench 440. However, the present disclosure is not limited thereto, and the first trench 430 and the second trench 440 may be formed at positions that do not correspond to each other in the third direction D3, as illustrated in FIG. 28. The first trench 430 may non-overlap the second trench 440 in the third direction D3. The first trench 430 and the second trench 440 may be provided in the same shape, or may be provided in different shapes. When the first trench 430 and the second trench 440 are provided in different shapes, for example, the first trench 430 may extend in an annular structure, and the second trench 440 may extend in a radial structure.

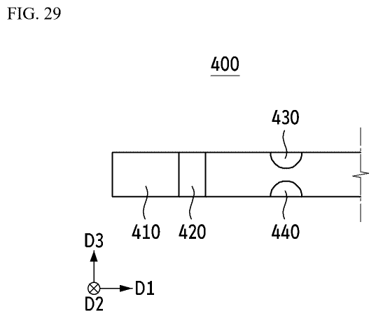

The magnetic field mask 400 may include a single-shaped pattern defined in its surface. However, the present disclosure is not limited thereto, and the magnetic field mask 400 may include patterns of various shapes. FIG. 29 illustrates a pattern within a magnetic field mask constituting a substrate treating apparatus of some embodiments of the present disclosure. Referring to FIG. 29, the magnetic field mask 400 may include the slit 420, the first trench 430, and the second trench 440. The first trench 430 and the second trench 440 may be formed at positions corresponding to each other or overlapping each other in the third direction D3, or may be formed at positions that do not correspond to each other or non-overlap each other in the third direction D3. Although not illustrated in the drawing, the magnetic field mask 400 may include one of the first trench 430 and the second trench 440 in addition to the slit 420.

As described above, the magnetic field mask 400 may include a pattern of a predetermined shape defined in the surface of the main body 410. In an embodiment, the pattern of the predetermined shape may include at least one of the slit 420, the first trench 430, and the second trench 440. Hereinafter, the pattern is described as including at least one of the slit 420, the first trench 430, and the second trench 440.

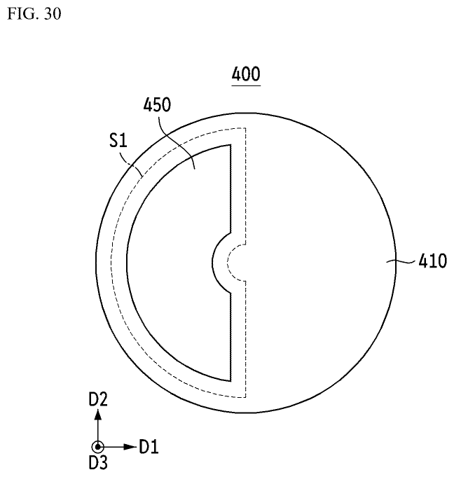

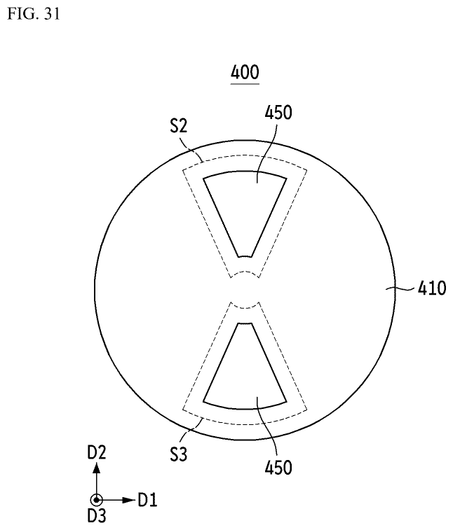

The pattern may be defined across an entire area of the main body 410, and the pattern may be defined in a symmetrical manner in the main body 410. However, the present disclosure is not limited thereto, and the pattern may be defined only in a partial area of the main body 410. FIG. 30 illustrates a pattern in a magnetic field mask constituting a substrate treating apparatus of some embodiments of the present disclosure. FIG. 31 illustrates a pattern in a magnetic field mask constituting a substrate treating apparatus of some embodiments of the present disclosure. Referring to FIG. 30, the pattern 450 may be formed in a first sub-area S1 of the main body 410 of the magnetic field mask 400. The first sub-area S1 may be positioned only at one side. The pattern 450 may be defined only in a partial area of the main body 410, and may be defined asymmetrically in the main body. The first sub-area S1 may have a semi-circle boundary extending around a center of the main body 410. For example, when viewed in a plan view, the semi-circle boundary of the first sub-area S1 may be adjacent to the center of the main body 410, extending around the center of the main body 410. Referring to FIG. 31, the pattern 450 may be formed in each of a second sub-area S2 and a third sub-area S3. The second sub-area S2 and the third sub-area S3 may be opposite to each other. The pattern 450 may be provided only in a partial area of the main body 410, and may be defined symmetrically in the main body. Each of the second sub-area S2 and the third sub-area S3 may have a boundary extending around a center of the main body 410. For example, when viewed in a plan view, the boundary of each of the second sub-area S2 and the third sub-area S3 may be adjacent to the center of the main body 410, extending around the center of the main body 410.

Various embodiments in which the magnetic field mask 400 is disposed on the upper surface of the process chamber 200 have been described above. In the present disclosure, it is obvious that the various embodiments as described above may be equally applied to a case when the magnetic field mask 400 is disposed on a side surface or a lower surface of the process chamber 200.

The present disclosure relates to each of the substrate treating apparatuses 150a, 150b, . . . , 150n including the magnetic field generator 300 and the customized magnetic field mask 400. According to the present disclosure, the magnetic field generator 300 and the magnetic field mask 400 may be used simultaneously to control the magnetic field to ensure uniform plasma density. Furthermore, controllability of the plasma density on a specific area within the process chamber 200 (i.e., Zone Controllability) may be secured, and peak positioning, broadening, or intensifying may be achieved depending on the shape of the magnetic field mask 400. With the magnetic field mask 400, the SCD distribution of etched features over the entire surface of a wafer may be improved. Furthermore, the substrate treating apparatus may have selective magnetic field interference capability, and thus, an ability to control the plasma density of the specific area to secure the precise plasma uniformity.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical concept or characteristics of the present disclosure. Therefore, it should be appreciated that the embodiments as described above are not restrictive but illustrative in all respects.

What is claimed is:

1. A substrate treating apparatus comprising:
a process chamber for treating a substrate;
a magnetic field generator spaced apart from an outer surface of the process chamber and configured to apply a first magnetic field to the process chamber; and
a magnetic field mask disposed in a space between the process chamber and the magnetic field generator and configured to apply a second magnetic field interfering with the first magnetic field,
wherein the magnetic field mask includes a ferromagnetic material.

2. The substrate treating apparatus of claim 1,
wherein the magnetic field mask contacts the outer surface of the process chamber.

3. The substrate treating apparatus of claim 1,
wherein the magnetic field mask is spaced apart from the outer surface of the process chamber.

4. The substrate treating apparatus of claim 3,
wherein the magnetic field mask is configured such that a distance between the magnetic field mask and the process chamber varies while the substrate is being treated.

5. The substrate treating apparatus of claim 1, further comprising:
a position adjuster connected to the magnetic field mask and configured to adjust a distance between the magnetic field mask and the process chamber.

6. The substrate treating apparatus of claim 1,
wherein the magnetic field mask has a main body and a pattern defined at a surface of the main body.

7. The substrate treating apparatus of claim 6,
wherein the pattern includes at least one of a hole-shaped slit extending through the main body and a groove-shaped trench.

8. The substrate treating apparatus of claim 7,
wherein the groove-shaped trench includes at least one of a first trench defined at an upper surface of the main body and a second trench defined at a lower surface of the main body.

9. The substrate treating apparatus of claim 8,
wherein the first trench and the second trench at least partially overlap each other in a third direction, and
wherein the third direction is perpendicular to the upper surface and the lower surface of the main body.

10. The substrate treating apparatus of claim 8,
wherein the first trench non-overlaps the second trench in a third direction, and
wherein the third direction is perpendicular to the upper surface and the lower surface of the main body.

11. The substrate treating apparatus of claim 6,
wherein the pattern is defined at a portion of the surface of the main body.

12. The substrate treating apparatus of claim 11,
wherein the pattern is formed only in a first sub-area of the main body, and
wherein the first sub-area has a semi-circle boundary extending around a center of the main body.

13. The substrate treating apparatus of claim 11,
wherein the pattern is formed only in a second sub-area and a third sub-area of the main body,
wherein the second sub-area and the third sub-area are opposite to each other, and
wherein each of the second sub-area and the third sub-area has a boundary extending around a center of the main body.

14. The substrate treating apparatus of claim 1,
wherein the magnetic field mask includes at least one of ferrite, permalloy, and silicon steel.

15. The substrate treating apparatus of claim 1,
wherein the outer surface of the process chamber includes at least one of an upper outer surface, a side outer surface, and a lower outer surface of the process chamber.

16. The substrate treating apparatus of claim 1,
wherein a vertical level of the magnetic field generator is equal to or higher than a vertical level of an electrode of the process chamber.

17. The substrate treating apparatus of claim 1,
wherein the substrate treating apparatus is configured to perform one of an etching process, a cleaning process, and a deposition process.

18. Semiconductor manufacturing equipment comprising:
a process processing module including a plurality of substrate treating apparatuses,
wherein one of the plurality of substrate treating apparatuses includes:
a process chamber for treating a substrate;
a magnetic field generator spaced apart from an outer surface of the process chamber and configured to apply a first magnetic field to the process chamber; and
a magnetic field mask disposed in a space between the process chamber and the magnetic field generator and configured to apply a second magnetic field interfering with the first magnetic field, and
wherein the magnetic field mask includes a ferromagnetic material.

19. The semiconductor manufacturing equipment of claim 18, further comprising:
a load port module on which a container containing the substrate therein is seated,
wherein one of an overhead transport apparatus moving along a rail installed at a ceiling of a semiconductor manufacturing plant and a ground-based transport apparatus moving on a ground of the semiconductor manufacturing plant transports the container to the load port module.

20. A substrate treating apparatus comprising:
a process chamber for treating a substrate;
a magnetic field generator spaced apart from an outer surface of the process chamber and configured to apply a first magnetic field to the process chamber; and
a magnetic field mask disposed in a space between the process chamber and the magnetic field generator and configured to apply a second magnetic field interfering with the first magnetic field,
wherein the magnetic field mask includes a ferromagnetic material,
wherein the ferromagnetic material includes at least one of ferrite, permalloy, and silicon steel,
wherein the magnetic field mask has a main body and a pattern defined at a surface of the main body,
wherein the pattern includes at least one of a slit of a shape of a hole extending through the main body, a first groove defined at an upper surface of the main body, and a second groove defined at a lower surface of the main body,
wherein the pattern is defined in a portion of the surface of the main body,
wherein the outer surface of the process chamber includes at least one of an upper outer surface, a side outer surface, and a lower outer surface of the process chamber, and
wherein the substrate treating apparatus is configured to perform one of an etching process, a cleaning process, and a deposition process.
